(19) United States
(12) Patent Application Publication
(10) Pub. No.: US 2023/0135600 A1
(43) Pub. Date: May 4, 2023

(54) LIGHT EMITTING ELEMENT, DISPLAY DEVICE INCLUDING THE SAME, AND METHOD OF FABRICATING THE DISPLAY DEVICE

(71) Applicant: Samsung Display Co., LTD., Yongin-si (KR)

(72) Inventors: Jin Taek PARK, Seoul (KR); Duk Sung KIM, Asan-si (KR); Soo Chul KIM, Hwaseong-si (KR); Dae Ho SONG, Hwaseong-si (KR); Byeong Hwa CHOI, Seoul (KR); Jin Woo CHOI, Seoul (KR)

(21) Appl. No.: 17/841,449

(22) Filed: Jun. 15, 2022

(30) Foreign Application Priority Data
Oct. 29, 2021 (KR) 10-2021-0146950

(51) Int. Cl. H01L 33/38; H01L 33/42; H01L 33/04; H01L 33/50; H01L 33/00

(52) U.S. Cl. CPC H01L 33/387; H01L 33/42; H01L 33/04; H01L 33/505; H01L 33/005; H01L 2933/0016

(57) ABSTRACT

A light emitting element, a display device including the same, and method of fabricating the display device are provided. The display device including a pixel electrode on a substrate, a light emitting element on the pixel electrode, and including a first semiconductor layer, an active layer on the first semiconductor layer, and a second semiconductor layer on the active layer, a connection electrode layer between the light emitting element and the pixel electrode, and directly contacting the pixel electrode, an insulating layer on the substrate and the pixel electrode, and surrounding the light emitting element, and a common electrode on the insulating layer directly contacting the second semiconductor layer of the light emitting element.

### CROSS-REFERENCE TO RELATED APPLICATION

This application claims priority to, and the benefit of, Korean Patent Application No. 10-2021-0146950 filed on Oct. 29, 2021 in the Korean Intellectual Property Office, the contents of which in its entirety are herein incorporated by reference.

### BACKGROUND

### 1. Field

The present disclosure relates to a light emitting element, a display device including the same, and a method of fabricating the display device.

### 2. Description of the Related Art

As the information society develops, demands for display devices for displaying images are increasing in various forms. The display devices may be flat panel displays, such as liquid crystal displays, field emission displays, and light emitting displays. The light emitting displays may include an organic light emitting display including an organic light emitting diode element as a light emitting element and an inorganic light emitting display including an inorganic semiconductor element as a light emitting element.

Recently, a head-mounted display including a light emitting display has been developed. The head-mounted display is a virtual reality (VR) or augmented reality (AR) glasses-type monitor device that is worn by a user in the form of glasses or a helmet, and forms a focus at a short distance in front of the eyes.

### SUMMARY

Aspects of the present disclosure provide a display device including light emitting elements, which are separated from a substrate using a sacrificial layer and each connected to an electrode through a connection electrode layer having a smooth surface, and a method of fabricating the display device.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to one or more embodiments of the disclosure, a display device includes a pixel electrode on a substrate, a light emitting element on the pixel electrode, and including a first semiconductor layer, an active layer on the first semiconductor layer, and a second semiconductor layer on the active layer, a connection electrode layer between the light emitting element and the pixel electrode, and directly contacting the pixel electrode, an insulating layer on the substrate and the pixel electrode, and surrounding the light emitting element, and a common electrode on the insulating layer directly contacting the second semiconductor layer of the light emitting element.

The light emitting element may further include an electrode layer between the connection electrode layer and the first semiconductor layer, wherein the connection electrode layer includes a first surface in contact with the electrode layer, and a second surface in contact with the pixel electrode, wherein the first surface is parallel to at least a part of the second surface.

A width of the first surface of the connection electrode layer may be the same as a width of the light emitting element.

The first surface may have a same width as the second surface.

A part of the second surface may be parallel to the first surface, and another part of the second surface is not parallel to the first surface.

The part of the second surface that is parallel to the first surface may directly contact the pixel electrode, wherein the part of the second surface that is not parallel to the first surface is spaced apart from the pixel electrode.

The part of the second surface that is not parallel to the first surface may be inclined.

The second surface that is not parallel to the first surface may be curved.

The connection electrode layer may include at least any one of aluminum (Al), copper (Cu), silver (Ag), gold (Au), tin (Sn), and titanium (Ti), wherein the electrode layer of the light emitting element includes at least any one of aluminum (Al), titanium (Ti), indium (In), gold (Au), silver (Ag), indium tin oxide (ITO), indium zinc oxide (IZO), and indium tin zinc oxide (ITZO).

At least a part of the light emitting element may protrude above the insulating layer.

The light emitting element may further include an electron blocking layer between the first semiconductor layer and the active layer, and a superlattice layer between the second semiconductor layer and the active layer.

The display device may further include a bank layer on the substrate, overlapping a part of the pixel electrode, and not overlapping the light emitting element.

The display device may further include a partition wall on the common electrode and defining an opening, a light conversion layer in the opening, and a color filter on the light conversion layer and the partition wall.

The partition wall may overlap the bank layer, wherein the opening overlaps the light emitting element.

According to one or more embodiments of the disclosure, a method of fabricating a display device includes forming a light emitting element by forming a sacrificial layer on a temporary substrate, forming a semiconductor material layer on the sacrificial layer, and etching the sacrificial layer and the semiconductor material layer, separating the light emitting element from the temporary substrate by removing a part of the sacrificial layer and forming a connection electrode layer on a surface of the light emitting element, and transferring the light emitting element, on which the connection electrode layer is formed, onto a first substrate on which pixel electrode is located.

The light emitting element may include an electrode layer on the connection electrode layer, a first semiconductor layer on the electrode layer, an active layer on the first semiconductor layer, and a second semiconductor layer on the active layer, wherein the connection electrode layer directly contacts the pixel electrode in the transferring of the light emitting element onto the first substrate.

The connection electrode layer may include a first surface in contact with the electrode layer, and a second surface in contact with the pixel electrode, wherein the first surface is parallel to at least a part of the second surface.

A thickness of the sacrificial layer may be greater than a thickness of the connection electrode layer.

According to one or more embodiments of the disclosure, a light emitting element includes a first semiconductor layer doped with a p-type dopant, a second semiconductor layer doped with an n-type dopant, an active layer between the first semiconductor layer and the second semiconductor layer, and an electrode layer on a surface of the first semiconductor layer, wherein a connection electrode layer is on a surface of the electrode layer, and includes a first surface in contact with the electrode layer, and a second surface opposite the first surface, and wherein the first surface is parallel to at least a part of the second surface.

The connection electrode layer may include at least any one of aluminum (Al), copper (Cu), silver (Ag), gold (Au), tin (Sn), and titanium (Ti), wherein the electrode layer of the light emitting element includes at least any one of aluminum (Al), titanium (Ti), indium (In), gold (Au), silver (Ag), indium tin oxide (ITO), indium zinc oxide (IZO), and indium tin zinc oxide (ITZO).

### BRIEF DESCRIPTION OF THE DRAWINGS

These and/or other aspects will become apparent and more readily appreciated from the following description of the embodiments, taken in conjunction with the accompanying drawings in which:

FIG. 1 is a plan view of a display device according to one or more embodiments;

FIG. 2 is a plan view illustrating the arrangement of a plurality of emission areas of the display device according to the embodiment;

FIG. 3 is a schematic cross-sectional view of the display device according to the embodiment;

FIG. 4 is a schematic cross-sectional view of a first emission area of FIG. 3;

FIG. 5 is an enlarged view of a light emitting element of FIG. 4;

FIG. 6 illustrates exit paths of light emitted from a light emitting element according to one or more embodiments;

FIG. 7 is an equivalent circuit diagram of a pixel of the display device according to the embodiment;

FIGS. 8 and 9 are circuit diagrams of pixels of display devices according to embodiments;

FIG. 10 is a flowchart illustrating a process of fabricating a display device according to one or more embodiments;

FIGS. 11 through 16 are cross-sectional views illustrating a part of the process of fabricating the display device according to the embodiment;

FIG. 17 is a cross-sectional view of a light emitting element included in a display device according to one or more embodiments;

FIG. 18 is a cross-sectional view of a light emitting element included in a display device according to one or more embodiments;

FIGS. 19 through 27 are views illustrating some operations of a transfer process of light emitting elements during a process of fabricating a display device according to one or more embodiments;

FIGS. 28 through 30 are schematic views of devices including a display device according to one or more embodiments; and

FIGS. 31 and 32 illustrate a transparent display device including a display device according to one or more embodiments.

### DETAILED DESCRIPTION

Aspects of some embodiments of the present disclosure and methods of accomplishing the same may be understood more readily by reference to the detailed description of embodiments and the accompanying drawings. Hereinafter, embodiments will be described in more detail with reference to the accompanying drawings. The described embodiments, however, may have various modifications and may be embodied in various different forms, and should not be construed as being limited to only the illustrated embodiments herein. Rather, these embodiments are provided as examples so that this disclosure will be thorough and complete, and will fully convey the aspects of the present disclosure to those skilled in the art, and it should be understood that the present disclosure covers all the modifications, equivalents, and replacements within the idea and technical scope of the present disclosure. Accordingly, processes, elements, and techniques that are not necessary to those having ordinary skill in the art for a complete understanding of the aspects of the present disclosure may not be described.

Unless otherwise noted, like reference numerals, characters, or combinations thereof denote like elements throughout the attached drawings and the written description, and thus, descriptions thereof will not be repeated. Further, parts that are not related to, or that are irrelevant to, the description of the embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the particular illustrated shapes of regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form in order to avoid unnecessarily obscuring various embodiments.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “plan view,” means viewing a target portion from the top, and the phrase “on a cross-section” means viewing a cross-section formed by vertically cutting a target portion from the side.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled,” or “directly on,” refers to one component directly connecting or coupling another component, or being on another component, without an intermediate component. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

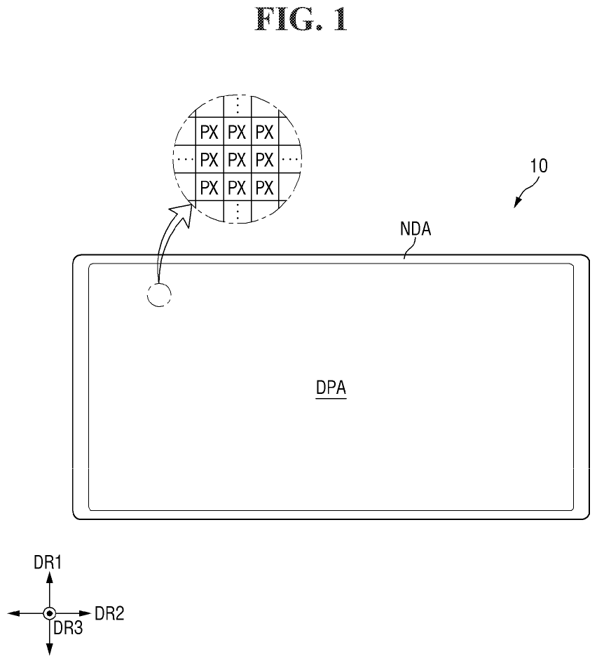

FIG. 1 is a plan view of a display device 10 according to one or more embodiments.

Referring to FIG. 1, the display device 10 displays moving images or still images. The display device 10 may refer to any electronic device that provides a display screen. Examples of the display device 10 may include televisions, notebook computers, monitors, billboards, the Internet of things (IoT), mobile phones, smartphones, tablet personal computers (PCs), electronic watches, smart watches, watch phones, head-mounted displays, mobile communication terminals, electronic notebooks, electronic books, portable multimedia players (PMPs), navigation devices, game machines, digital cameras and camcorders, all of which provide a display screen.

The display device 10 includes a display panel that provides a display screen. Examples of the display panel may include inorganic light emitting diode display panels, organic light emitting display panels, quantum dot light emitting display panels, plasma display panels, and field emission display panels. A display device in which inorganic light emitting diodes are located on a semiconductor circuit board will be described below as an example of the display panel, but the present disclosure is not limited to this case, and other display panels can also be applied as long as the same technical spirit is applicable.

The shape of the display device 10 can be variously modified. For example, the display device 10 may have various shapes such as a horizontally long rectangle, a vertically long rectangle, a square, a quadrangle with rounded corners (vertices), other polygons, and a circle. The shape of a display area DPA of the display device 10 may also be similar to the overall shape of the display device 10. In FIG. 1, the display device 10 shaped like a rectangle that is long in a second direction DR2 is illustrated.

In the present specification, the first direction DR1 refers to a vertical direction of the display device 10, the second direction DR2 refers to a horizontal direction of the display device 10, and a third direction DR3 refers to a thickness direction of the display device 10. In the present specification, “above,” “top” and “upper surface” indicate one side in the third direction DR3, and “below,” “bottom” and “lower surface” indicate the other side in the third direction DR3. “Left,” “right,” “up,” and “down” indicate directions when the drawing is seen in plan view. For example, “up” and “down” indicate the first direction DR1, and “left” and “right” indicate the second direction DR2.

The display device 10 may include the display area DPA and a non-display area NDA. The display area DPA is an area where a screen can be displayed, and the non-display area NDA is an area where no screen is displayed. The display area DPA may also be referred to as an active area, and the non-display area NDA may also be referred to as an inactive area. The display area DPA may be generally located in the center of the display device 10.

The non-display area NDA may be located around the display area DPA. The non-display area NDA may entirely or partially surround the display area DPA. The display area DPA may be rectangular, and the non-display area NDA may be located adjacent to four sides of the display area DPA. The non-display area NDA may form a bezel of the display device 10. In each non-display area NDA, wirings or circuit drivers included in the display device 10 may be located, or external devices may be mounted.

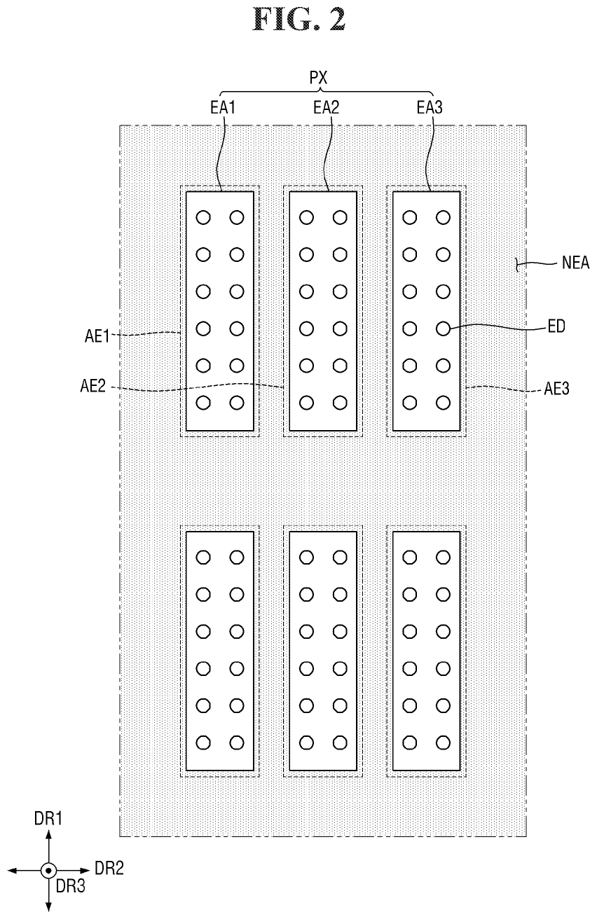

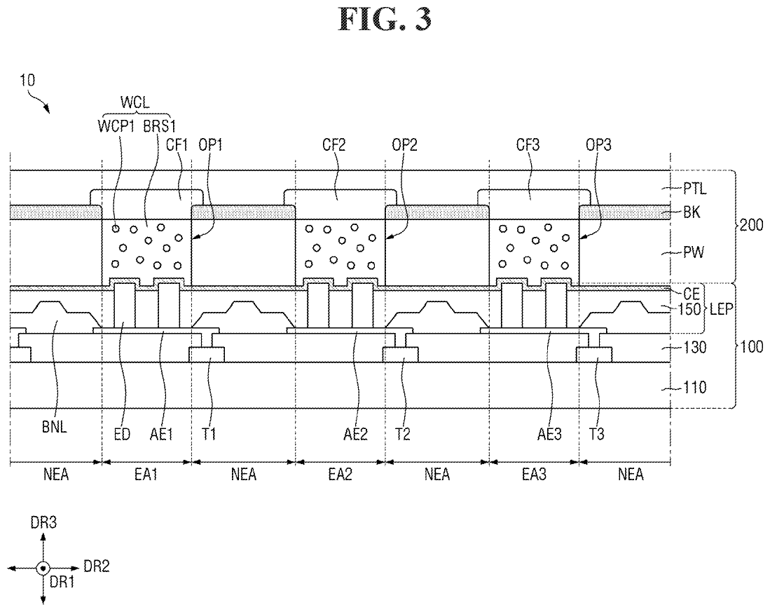

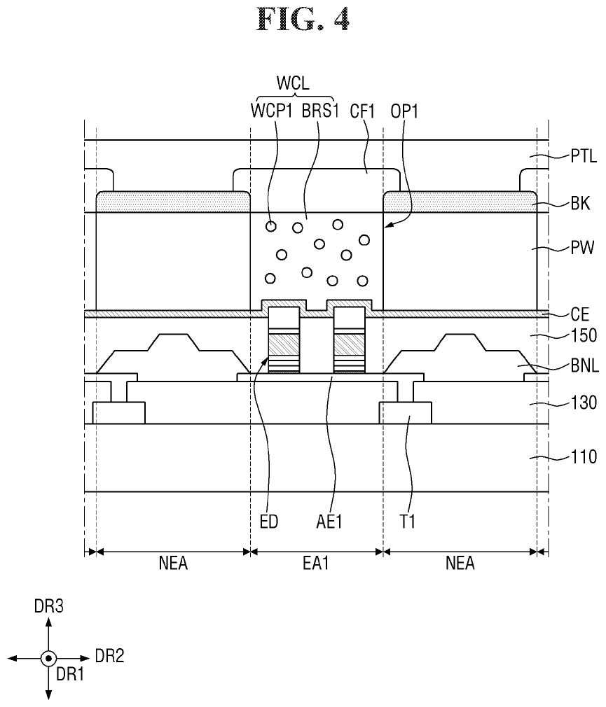

FIG. 2 is a plan view illustrating the arrangement of a plurality of emission areas EA1 through EA3 of the display device 10 according to one or more embodiments. FIG. 3 is a schematic cross-sectional view of the display device 10 according to one or more embodiments. FIG. 4 is a schematic cross-sectional view of a first emission area EA1 of FIG. 3.

Referring to FIGS. 2 through 4, the display device 10 may include a plurality of pixels PX. The pixels PX may be arranged in a matrix direction. Each of the pixels PX may be rectangular or square in plan view. However, the present disclosure is not limited thereto, and each of the pixels PX may also have a rhombus shape having each side inclined with respect to a direction. The pixels PX may be arranged in a stripe type or an island type. In addition, each of the pixels PX may display a corresponding color by including one or more light emitting elements which emit light of a corresponding wavelength band.

Each of the pixels PX may include a plurality of emission areas EA1 through EA3. In the display device 10, one pixel PX composed of the emission areas EA1 through EA3 may have a minimum light emitting unit.

For example, one pixel PX may include a first emission area EA1, a second emission area EA2, and a third emission area EA3. The first emission area EA1 may emit light of a first color, the second emission area EA2 may emit light of a second color, and the third emission area EA3 may emit light of a third color. For example, the first color may be red, the second color may be green, and the third color may be blue. However, the present disclosure is not limited thereto, and the emission areas EA1 through EA3 may also emit light of the same color. In one or more embodiments, one pixel PX may include three emission areas EA1 through EA3. However, the present disclosure is not limited thereto. For example, one pixel PX may also include four or more emission areas.

The emission areas EA1 through EA3 may be arranged in the first direction DR1 and the second direction DR2, and the first emission area EA1, the second emission area EA2, and the third emission area EA3 may be alternately arranged in the second direction DR2. Because the pixels PX are arranged in the first direction DR1 and the second direction DR2, the first emission area EA1, the second emission area EA2, and the third emission area EA3 may be sequentially arranged in the second direction DR2, and this arrangement may be repeated. In addition, each of the first emission area EA1, the second emission area EA2, and the third emission area EA3 may be repeatedly arranged in the first direction DR1.

The display device 10 may include a display substrate 100, and a wavelength converter 200 located on the display substrate 100. The display substrate 100 may include a first substrate 110 and anodes AE1 through AE3, a plurality of light emitting elements ED, and a cathode CE located on the first substrate 110. The display device 10 may further include switching elements T1 through T3, insulating layers 130 and 150, a partition wall PW, light conversion layers WCL, a light blocking member BK, color filters CF1 through CF3, and a protective layer PTL on the first substrate 110. The wavelength converter 200 may include the light conversion layers WCL, the light blocking member BK, the color filters CF1 through CF3, and the protective layer PTL.

The first substrate 110 may be an insulating substrate. The first substrate 110 may include a transparent material. For example, the first substrate 110 may include a transparent insulating material, such as glass or quartz. The first substrate 110 may be a rigid substrate. However, the present disclosure is not limited thereto, and the first substrate 110 may also include plastic such as polyimide, and may have flexible properties so that it can be curved, bent, folded, and/or rolled. The first substrate 110 may include a plurality of emission areas EA1 through EA3 and a non-emission area NEA.

The switching elements T1 through T3 may be on the first substrate 110. In one or more embodiments, the switching elements T1 through T3 may include a first switching element T1 located in the first emission area EA1, a second switching element T2 located in the second emission area EA2, and a third switching element T3 located in the third emission area EA3. In some embodiments, the display device 10 may further include a switching element in the non-emission area NEA.

In one or more embodiments, each of the first switching transistor T1, the second switching transistor T2, and the third switching transistor T3 may be a thin-film transistor including amorphous silicon, polysilicon, or an oxide semiconductor. In some embodiments, a plurality of signal lines (e.g., a gate line, a data line, a power line, etc.) for transmitting signals to each switching element may also be on the first substrate 110.

A first insulating layer 130 may be on the first substrate 110 and the switching elements T1 through T3. In one or more embodiments, the first insulating layer 130 may include an organic insulating layer to compensate for a step difference due to the switching elements T1 through T3. For example, the first insulating layer 130 may include acrylic resin, epoxy resin, imide resin, ester resin, or the like. In one or more embodiments, the first insulating layer 130 may include a positive photosensitive material or a negative photosensitive material.

A light emitting element unit LEP may be on the first insulating layer 130. The light emitting element unit LEP may include the anodes AE1 through AE3, the light emitting elements ED, and the cathode CE.

The anodes AE1 through AE3 may be on the first insulating layer 130. The anodes AE1 through AE3 may be located to correspond to the emission areas EA1 through EA3, respectively. Like the emission areas EA1 through EA3, the anodes AE1 through AE3 may be spaced apart from each other in the first direction DR1 and the second direction DR2. Each of the anodes AE1 through AE3 may have a quadrangular shape including sides extending in the first direction DR1 and in the second direction DR2 in plan view. However, the present disclosure is not limited thereto, and the planar shape of the anodes AE1 through AE3 may be variously modified according to the arrangement and structure of the emission areas EA1 through EA3 of the display device 10. For example, when the emission areas EA1 through EA3 are arranged in a PENTILE™ type (e.g., a RGBG matrix structure, a PENTILE™ matrix structure, a PENTILE™ structure, or an RGBG structure, PENTILE™ being a registered trademark of Samsung Display Co., Ltd., Republic of Korea), the arrangement of the anodes AE1 through AE3 may be changed accordingly, and the planar shape of each of the anodes AE1 through AE3 may also be modified to a polygonal shape, a circular shape, or the like.

The anodes AE1 through AE3 may include a first anode AE1 in the first emission area EA1, a second anode AE2 in the second emission area EA2, and a third anode AE3 in the third emission area EA3. The first anode AE1 may penetrate the first insulating layer 130, and may be electrically connected to the first switching element T1. The second anode AE2 may penetrate the first insulating layer 130, and may be electrically connected to the second switching element T2. The third anode AE3 may penetrate the first insulating layer 130, and may be electrically connected to the third switching element T3. An anode AE may be a pixel electrode corresponding to each emission area EA.

The first anode AE1, the second anode AE2, and the third anode AE3 may include a material having high reflectivity. For example, the first anode AE1, the second anode AE2, and the third anode AE3 may have a structure in which a material layer having a high work function, such as titanium oxide (TiO₂), indium tin oxide (ITO), indium zinc oxide (IZO), zinc oxide (ZnO), indium tin zinc oxide (ITZO) or magnesium oxide (MgO) and a material layer having high reflectivity such as silver (Ag), magnesium (Mg), aluminum (Al), platinum (Pt), lead (Pd), gold (Au), nickel (Ni), neodymium (Nd), iridium (Ir), chromium (Cr), lithium (Li), calcium (Ca), or a mixture of the same are stacked. The material layer having a high work function may be on the material layer having high reflectivity so that it is adjacent to the light emitting elements ED. The first anode AE1, the second anode AE2, and the third anode AE3 may have a multilayer structure of ITO/Mg, ITO/MgF, ITO/Ag, or ITO/Ag/ITO, but the present disclosure is not limited thereto.

A bank layer BNL may be on the first insulating layer 130 and the anodes AE1 through AE3. The bank layer BNL may include a plurality of openings partially exposing the anodes AE1 through AE3, respectively. The openings of the bank layer BNL may separate the emission areas EA1 through EA3 and the non-emission area NEA. For example, among the openings of the bank layer BNL, an opening exposing the first anode AE1 may be the first emission area EA1, and openings exposing the second anode AE2 and the third anode AE3 may be the second emission area EA2 and the third emission area EA3, respectively. The other area in which the bank layer BNL is located may be the non-emission area NEA.

The bank layer BNL may include an organic insulating material such as polyacrylates resin, epoxy resin, phenolic resin, polyamides resin, polyimides resin, unsaturated polyesters resin, polyphenylenethers resin, polyphenylenesulfides resin, or benzocyclobutene (BCB).

The light emitting elements ED may be on the anodes AE1 through AE3. The light emitting elements ED may be on the anode AE1, AE2, or AE3 in each of the emission areas EA1 through EA3. The light emitting elements ED may not overlap the bank layer BNL, and may be located between parts of the bank layer BNL that separate adjacent emission areas EA1 through EA3.

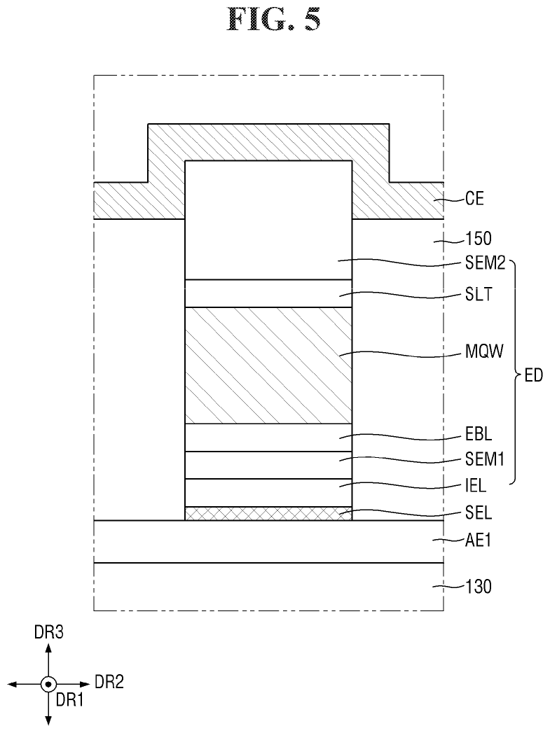

The light emitting elements ED may be inorganic light emitting diode elements. Each of the light emitting elements ED may include a plurality of semiconductor layers SEM1, SEM2, EBL, and SLT (see FIG. 5), an active layer MQW (see FIG. 5), and an electrode layer IEL (see FIG. 5) and may emit light in response to an electrical signal. The light emitting elements ED may extend in the third direction DR3. The light emitting elements ED may be longer in the third direction DR3 than in the horizontal direction. For example, the light emitting elements ED may have a length of about 1 μm to about 5 μm in the third direction DR3. In some embodiments, each of the light emitting elements ED may be shaped like a cylinder, a disk, or a rod whose width is greater than its height. However, the present disclosure is not limited thereto, and each of the light emitting elements ED may also have various shapes including shapes such as a rod, a wire, and a tube, polygonal prisms such as a cube, a rectangular parallelepiped, and a hexagonal prism, and a shape extending in a direction and having a partially inclined outer surface. The light emitting elements ED will be described in more detail later.

A second insulating layer 150 may be on the bank layer BNL and the anodes AE1 through AE3. The second insulating layer 150 may planarize a step thereunder so that the cathode CE to be described later can be formed. The second insulating layer 150 may be formed to a height (e.g., predetermined height) so that a part of each of the light emitting elements ED can protrude above the second insulating layer 150. The height of the second insulating layer 150 from upper surfaces of the anodes AE1 through AE3 may be lower than heights of the light emitting elements ED, and a part of each of the light emitting elements ED may protrude above an upper surface of the second insulating layer 150. The second insulating layer 150 may cover the light emitting elements ED.

The second insulating layer 150 may include an organic insulating material. For example, the second insulating layer 150 may include polyacrylates resin, epoxy resin, phenolic resin, polyamides resin, polyimides resin, unsaturated polyesters resin, polyphenylenethers resin, polyphenylenesulfides resin, or benzocyclobutene (BCB).

The cathode CE may be on the second insulating layer 150 and the light emitting elements ED. For example, the cathode CE may be on a surface of the first substrate 110 on which the light emitting elements ED are formed, and may be entirely in the display area DPA and the non-display area NDA. The cathode CE may overlap each of the emission areas EA1 through EA3 in the display area DPA, and may have a relatively small thickness to allow light to pass therethrough.

The cathode CE may be directly on upper surfaces of some of the light emitting elements ED. The cathode CE may cover the light emitting elements ED, and may be a common layer or a common electrode to which the light emitting elements ED are commonly connected. A common voltage may be applied to each light emitting element ED.

Because the cathode CE is entirely on the first substrate 110 to receive a common voltage, it may include a material having low resistance. In addition, the cathode CE may be formed to have a small thickness or may be formed of a transparent material to easily transmit light. For example, the cathode CE may include a material having low resistance such as aluminum (Al), silver (Ag), copper (Cu), ITO, or IZO. A thickness of the cathode CE may be, but is not limited to, about 10 to 200 Å.

Each of the light emitting elements ED may receive a pixel voltage from the anode AE1, AE2, or AE3 through a connection electrode layer SEL, and may receive a common voltage through the cathode CE. Each of the light emitting elements ED may emit light with a luminance (e.g., predetermined luminance) according to a voltage difference between the pixel voltage and the common voltage.

The partition wall PW may be on the cathode CE of the display area DPA and, like the bank layer BNL, may separate the emission areas EA1 through EA3. The partition wall PW may extend in the first direction DR1 and the second direction DR2, and may form a grid pattern in the entire display area DPA. In addition, the partition wall PW may not overlap the emission areas EA1 through EA3, and may overlap the non-emission area NEA and the bank layer BNL.

The partition wall PW may include a plurality of openings OP1 through OP3 exposing the cathode CE. The openings OP1 through OP3 may include a first opening OP1 overlapping the first emission area EA1, a second opening OP2 overlapping the second emission area EA2, and a third opening OP3 overlapping the third emission area EA3. Here, the openings OP1 through OP3 may correspond to the emission areas EA1 through EA3. That is, the first opening OP1 may correspond to the first emission area EA1, the second opening OP2 may correspond to the second emission area EA2, and the third opening OP3 may correspond to the third emission area EA3. Each of the openings OP1 through OP3 may overlap the light emitting elements ED in the emission area EA1, EA2, or EA3.

The partition wall PW may provide spaces for the light conversion layers WCL to be located. To this end, the partition wall PW may have a thickness (e.g., predetermined thickness). For example, the thickness of the partition wall PW may be in the range of about 1 μm to about 10 μm. The partition wall PW may include an organic insulating material to have a thickness (e.g., predetermined thickness). The organic insulating material may include, for example, epoxy resin, acrylic resin, cardo resin, or imide resin.

The light conversion layers WCL may be on the openings OP1 through OP3, respectively, and may be spaced apart from each other. The light conversion layers WCL may be formed as island-shaped patterns spaced apart from each other. For example, the light conversion layers WCL may be in the first opening OP1, the second opening OP2, and the third opening OP3, respectively, and may correspond one-to-one to them. In addition, the light conversion layers WCL may overlap the first emission area EA1, the second emission area EA2, and the third emission area EA3, respectively. In one or more embodiments, the light conversion layers WCL may completely overlap the first emission area EA1, the second emission area EA2, and the third emission area EA3, respectively. However, the present disclosure is not limited thereto, and the light conversion layers WCL may also be formed as linear patterns extending in a direction.

The light conversion layers WCL may convert or shift light emitted from the light emitting elements ED into light of a different wavelength, and may output the light to the color filters CF1 through CF3. Each of the light conversion layers WCL may include a base resin BRS1 and light conversion particles WCP1. The base resin BRS1 may include a light-transmitting organic material. For example, the base resin BRS1 may include epoxy resin, acrylic resin, cardo resin, or imide resin.

The light conversion particles WCP1 may convert blue light of the third color incident from the light emitting elements ED into light of a fourth color. For example, the wavelength conversion particles WCP1 may convert light of a blue wavelength band into light of a yellow wavelength band. The wavelength conversion particles WCP1 may be quantum dots, quantum rods, fluorescent materials, or phosphorescent materials. For example, the quantum dots may be particulate materials that emit light of a corresponding color when electrons transition from a conduction band to a valence band.

The quantum dots may be semiconductor nanocrystalline materials. The quantum dots may have a corresponding band gap according to their composition and size. Thus, the quantum dots may absorb light and then emit light having a unique wavelength. Examples of semiconductor nanocrystals of the quantum dots include Group IV nanocrystals, Group II-VI compound nanocrystals, Group III-V compound nanocrystals, Group IV-VI nanocrystals, and combinations of the same.

In one or more embodiments, the quantum dots may have a core-shell structure including a core containing a nanocrystal and a shell surrounding the core. The shell of each quantum dot may serve as a protective layer for maintaining semiconductor characteristics by reducing or preventing chemical denaturation of the core and/or as a charging layer for giving electrophoretic characteristics to the quantum dot. The shell may be a single layer or a multilayer. The shell of each quantum dot may be, for example, a metal or non-metal oxide, a semiconductor compound, or a combination of the same.

Each of the light conversion layers WCL may further include scatterers for scattering light of the light emitting elements ED in random directions. The scatterers may have a refractive index different from that of the base resin BRS1, and may form an optical interface with the base resin BRS1. For example, the scatterers may be light scattering particles. The scatterers are not particularly limited as long as they are materials that can scatter at least a part of transmitted light. However, the scatterers may be, for example, metal oxide particles or organic particles. Examples of the metal oxide may include titanium oxide (TiO₂), zirconium oxide (ZrO₂), aluminum oxide (Al₂O₃), indium oxide (In₂O₃), zinc oxide (ZnO) and tin oxide (SnO₂), and examples of the organic particles may include acrylic resin and urethane resin. The scatterers may scatter incident light in random directions regardless of the incident direction of the incident light without substantially converting the wavelength of the incident light.

As a thickness of each wavelength conversion layer WCL in the third direction DR3 increases, the content of the wavelength conversion particles WCP1 included in the light conversion layer WCL increases, thereby increasing the light conversion efficiency of the light conversion layer WCL. Therefore, the thickness of each of the light conversion layers WCL may be set in consideration of the light conversion efficiency of the light conversion layer WCL.

A part of the blue light of the third color emitted from the light emitting elements ED may be converted into yellow light of the fourth color by the light conversion layers WCL. In the light conversion layers WCL, the blue light of the third color and the yellow light of the fourth color may be mixed to output white light of a fifth color. Among the white light output from the light conversion layers WCL, only first light may be transmitted through a first color filter CF1 to be described later, only second light may be transmitted through a second color filter CF2, and only third light may be transmitted through a third color filter CF3. Accordingly, light output from the color filters CF1 through CF3 may be respectively red light of the first color, green light of the second color, and blue light of the third color. Thus, a full spectrum of color can be realized.

The light blocking member BK may be on the partition wall PW. The light blocking member BK may overlap the non-emission area NEA, and may block transmission of light. Like the bank layer BNL, the light blocking member BK may be in a grid shape in plan view. The light blocking member BK may overlap the bank layer BNL, and may not overlap the emission areas EA1 through EA3.

In one or more embodiments, the light blocking member BK may include an organic light blocking material, and may be formed by coating and exposing the organic light blocking material. The light blocking member BK may include a dye or pigment having light blocking properties, and may be a black matrix.

The color filters CF1 through CF3 may be on the partition wall PW. The color filters CF1 through CF3 may be located to respectively correspond to areas exposed by the light blocking member BK. Different color filters CF1 through CF3 may be spaced apart from each other, but the present disclosure is not limited thereto.

The color filters CF1 through CF3 may include the first color filter CF1, the second color filter CF2, and the third color filter CF3. The first color filter CF1 may overlap the first emission area EA1. The second color filter CF2 may overlap the second emission area EA2 of the bank layer BNL, and the third color filter CF3 may overlap the third emission area EA3 of the bank layer BNL.

The color filters CF1 through CF3 may respectively fill the areas exposed by the light blocking member BK, and may be partially on the light blocking member BK. However, the present disclosure is not limited thereto, and the color filters CF1 through CF3 may also be located within the areas exposed by the light blocking member BK. Each of the color filters CF1 through CF3 may be located as an island-shaped pattern, but the present disclosure is not limited thereto. For example, each of the color filters CF1 through CF3 may form a linear pattern extending in a direction in the display area DPA. In one or more embodiments, the first color filter CF1 may be a red color filter, the second color filter CF2 may be a green color filter, and the third color filter CF3 may be a blue color filter. Each of the color filters CF1 through CF3 may transmit only a part of light emitted from the light emitting elements ED, and may block transmission of the other light. In the display device 10, because light emitted from the light emitting elements ED is output through the color filters CF1 through CF3, color purity can be further improved.

The protective layer PTL may be on the color filters CF1 through CF3 and the light blocking member BK. The protective layer PTL may be located at the top of the display device 10 to protect the color filters CF1 through CF3 and the light blocking member BK thereunder. A surface (e.g., a lower surface) of the protective layer PTL may contact the color filters CF1 through CF3 and an upper surface of the light blocking member BK.

The protective layer PTL may include an inorganic insulating material to protect the color filters CF1 through CF3 and the light blocking member BK. For example, the protective layer PTL may include, but is not limited to, silicon oxide (SiOₓ), silicon nitride (SiNₓ), silicon oxynitride (SiOxNy), aluminum oxide (AlOₓ), or aluminum nitride (AlNₓ). The protective layer PTL may have a thickness (e.g., predetermined thickness) in the range of, for example, about 0.01 μm to about 1 μm. However, the present disclosure is not limited thereto.

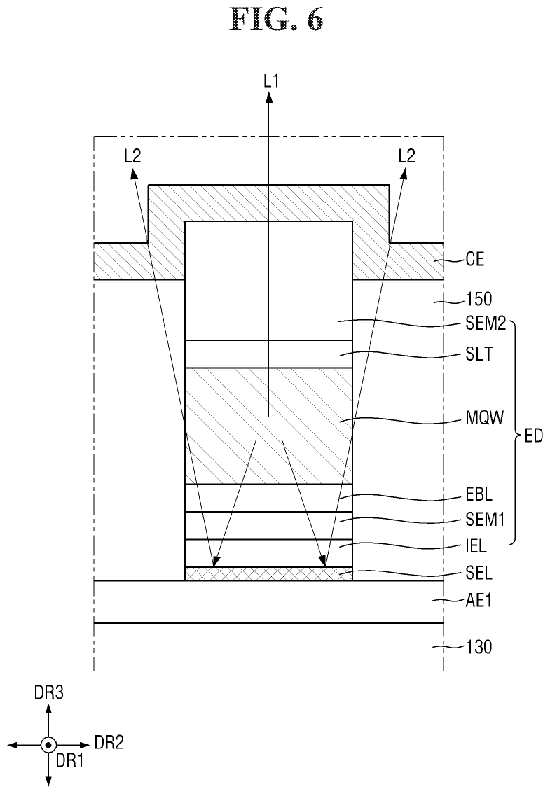

FIG. 5 is an enlarged view of a light emitting element ED of FIG. 4. FIG. 6 illustrates exit paths of light emitted from a light emitting element ED according to one or more embodiments.

Referring to FIGS. 5 and 6 in conjunction with FIGS. 3 and 4, the light emitting element ED may include an electrode layer IEL, a first semiconductor layer SEM1, an electron blocking layer EBL, an active layer MQW, a superlattice layer SLT, and a second semiconductor layer SEM2. The electrode layer IEL, the first semiconductor layer SEM1, the electron blocking layer EBL, the active layer MQW, the superlattice layer SLT, and the second semiconductor layer SEM2 may be sequentially stacked in the third direction DR3.

The first semiconductor layer SEM1 may be on the electrode layer IEL. The first semiconductor layer SEM1 may be a p-type semiconductor, and may include a semiconductor material having a chemical formula of AlₓGa_{y}In_{1-x-y}N (0≤x≤1, 0≤y≤1, 0≤x+y≤1). For example, the first semiconductor layer SEM1 may be any one or more of p-type doped AlGaInN, GaN, AlGaN, InGaN, AlN, and InN. The first semiconductor layer SEM1 may be doped with a p-type dopant, and the p-type dopant may be Mg, Zn, Ca, Ba, or the like. For example, the first semiconductor layer SEM1 may be p-GaN doped with p-type Mg.

The electron blocking layer EBL may be on the first semiconductor layer SEM1. The electron blocking layer EBL may reduce or prevent electrons flowing into the active layer MQW from being injected into another layer without recombining with holes in the active layer MQW. For example, the electron blocking layer EBL may be p-AlGaN doped with p-type Mg. As a nonlimiting example, thickness of the electron blocking layer EBL may be in the range of about 10 nm to about 50 nm. In some embodiments, the electron blocking layer EBL may be omitted.

The active layer MQW may be on the electron blocking layer EBL. The active layer MQW may emit light through recombination of electrons-holes according to an emission signal received though the first semiconductor layer SEM1 and the second semiconductor layer SEM2. The active layer MQW may include a material having a single or multiple quantum well structure. When the active layer MQW includes a material having a multiple quantum well structure, it may have a structure in which a plurality of well layers and a plurality of barrier layers are alternately stacked. Here, the well layers may be formed of InGaN, and the barrier layers may be formed of GaN or AlGaN, but the present disclosure is not limited thereto. For example, the active layer MQW may also have a structure in which a semiconductor material having a relatively large band gap energy and a semiconductor material having a relatively small band gap energy are alternately stacked, or may include different Group 3 to 5 semiconductor materials depending on the wavelength band of light that it emits.

The superlattice layer SLT is on the active layer MQW. The superlattice layer SLT may relieve stress due to a difference in lattice constant between the second semiconductor layer SEM2 and the active layer MQW. For example, the superlattice layer SLT may be formed of InGaN or GaN. A thickness of the superlattice layer SLT may be about 50 nm to about 200 nm. However, the superlattice layer SLT may also be omitted.

The second semiconductor layer SEM2 may be on the superlattice layer SLT. The second semiconductor layer SEM2 may be an n-type semiconductor. The second semiconductor layer SEM2 may include a semiconductor material having a chemical formula of AlₓGa_{y}In_{1-x-y}N (0≤x≤1, 0≤y≤1, 0≤x+y≤1). For example, the second semiconductor layer SEM2 may be any one or more of n-type doped AlGaInN, GaN, AlGaN, InGaN, AlN, and InN. The second semiconductor layer SEM2 may be doped with an n-type dopant, and the n-type dopant may be Si, Ge, Sn, or the like. For example, the second semiconductor layer SEM2 may be n-GaN doped with n-type Si. As a nonlimiting example, a thickness of the second semiconductor layer SEM2 may be in the range of about 2 μm to about 4 μm.

The electrode layer IEL may be located between the connection electrode layer SEL and the first semiconductor layer SEM1. When the light emitting element ED is connected to the connection electrode layer SEL or the anode AE1, AE2, or AE3 in the display device 10, the electrode layer IEL may reduce the resistance between the light emitting element ED and an electrode or a contact electrode. The electrode layer IEL may include a conductive metal. For example, the electrode layer IEL may include at least any one of aluminum (Al), titanium (Ti), indium (In), gold (Au), silver (Ag), indium tin oxide (ITO), indium zinc oxide (IZO), and indium tin zinc oxide (ITZO). In addition, the electrode layer IEL may include an n-type or p-type doped semiconductor material. However, the present disclosure is not limited thereto.

The display device 10 may further include the connection electrode layer SEL located between the light emitting element ED and the anode AE1, AE2, or AE3. The connection electrode layer SEL may be directly on the anode AE1, AE2, or AE3. The connection electrode SEL may directly contact the anode AE1, AE2, or AE3 and the light emitting element ED to electrically connect them. The connection electrode layer SEL may be an ohmic connection electrode or a Schottky connection electrode. In one or more embodiments in which a plurality of light emitting elements ED are in each emission area EA1, EA2 or EA3, a plurality of connection electrode layers SEL may be on the anode AE1, AE2, or AE3 in each emission area EA1, EA2 or EA3.

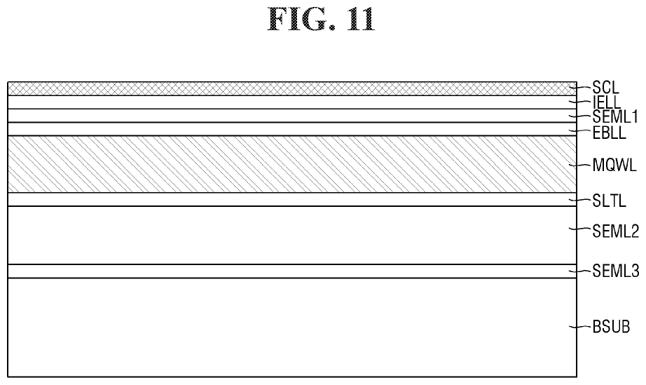

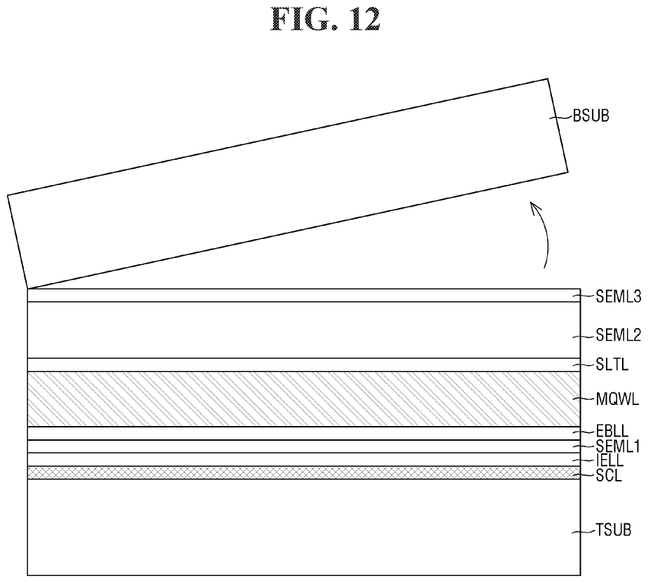

The light emitting element ED may be formed on a substrate other than the first substrate 110 of the display device 10, and may be transferred from the substrate to the first substrate 110. A process of fabricating the display device 10 may include a process of separating the substrate and the light emitting element ED. The separation process may be performed through a process of forming a sacrificial layer SCL (see FIG. 11) on the light emitting element ED, transferring the light emitting element ED, on which the sacrificial layer SCL is formed, to a temporary substrate TSUB (see FIG. 12), and then removing a part of the sacrificial layer SCL. The sacrificial layer SCL may include a material that can be removed relatively easily in the separation process and has high conductivity. The sacrificial layer SCL may not be completely removed when the light emitting element ED is separated but may remain as the connection electrode layer SEL. The light emitting element ED may be transferred onto the first substrate 110 so that the connection electrode layer SEL formed of the remaining sacrificial layer SCL is on the anode AE1, AE2, or AE3, and may be electrically connected to the anode AE1, AE2, or AE3 through the connection electrode layer SEL.

For example, the connection electrode layer SEL may include at least any one of metal materials such as gold (Au), copper (Cu), tin (Sn), titanium (Ti), aluminum (Al), and silver (Ag). Because the connection electrode layer SEL is connected to the anode AE1, AE2, or AE3 by directly contacting the anode AE1, AE2, or AE3, it may be made of the same material as the anode AE1, AE2, or AE3. Accordingly, adhesion between the connection electrode layer SEL and the anode AE1, AE2, or AE3 may be improved, thereby increasing contact characteristics.

As will be described later, the sacrificial layer SCL may be etched together with a semiconductor material layer in a process of forming the light emitting element ED, and the connection electrode layer SEL formed of the remaining sacrificial layer SCL may have the same width as the light emitting element ED. The connection electrode layer SEL may include a first surface in contact with the electrode layer IEL of the light emitting element ED, and a second surface in contact with the anode AE1, AE2, or AE3. The first surface and the second surface of the connection electrode layer SEL may be parallel to each other and may have the same width. The first surface of the connection electrode layer SEL may completely contact a lower surface of the electrode layer IEL, and the second surface may completely contact the anode AE1, AE2, or AE3. However, the present disclosure is not limited thereto. In a process of removing the sacrificial layer SCL, which will be descried later, the shape of the connection electrode layer SEL may be different from that in the embodiments corresponding to FIGS. 5 and 6 depending on process conditions. In this case, the first surface and the second surface of the connection electrode layer SEL may not be partially parallel to each other, and parallel surfaces may have different widths.

According to one or more embodiments, the sacrificial layer SCL and the connection electrode layer SEL may include a material having high reflectivity, and some of the light generated by the light emitting element ED may be reflected by the connection electrode layer SEL to travel upward. Light generated by the active layer MQW of the light emitting element ED may be emitted in random directions.

Among the light, first light L1 emitted upward above the first substrate 110 or above the anode AE1, AE2, or AE3 may be incident on the cathode CE through an upper surface of the second semiconductor layer SEM2 of the light emitting element ED. The cathode CE may be made of a material having high light transmittance or may have a relatively small thickness, and the first light L1 may pass through the cathode CE to travel upward.

Among the light generated by the active layer MQW, second light L2 emitted toward the first substrate 110 or toward the anode AE1, AE2, or AE3 may be incident toward the connection electrode layer SEL. The connection electrode layer SEL may be made of a material having relatively high reflectivity, and the second light L2 may be reflected by the connection electrode layer SEL to travel upward. Because the display device 10 includes the connection electrode layer SEL remaining after the separation process of the light emitting element ED, upward emission efficiency of light generated by the light emitting element ED can be improved.

Each pixel PX includes a pixel driving circuit. The pixel driving circuit may include a transistor and a capacitor. The number of transistors and capacitors in each pixel driving circuit can be variously changed. The pixel driving circuit will be described below using a 3T1C structure in which the pixel driving circuit includes three transistors and one capacitor as an example. However, the present disclosure is not limited thereto, and other various modified pixel structures such as a 2T1C structure, a 7T1C structure, and a 6T1C structure are also applicable.

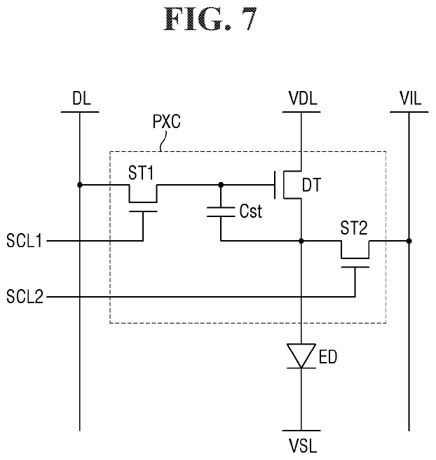

FIG. 7 is an equivalent circuit diagram of a pixel of the display device 10 according to one or more embodiments. FIG. 7 illustrates an example of a pixel circuit diagram of one pixel PX of FIG. 2.

Referring to FIG. 7, a light emitting element ED emits light according to a driving current. The amount of light emitted from the light emitting element ED may be proportional to the driving current. The light emitting element ED may be an inorganic light emitting element including an anode, a cathode, and an inorganic semiconductor located between the anode and the cathode.

The light emitting element ED may have the anode connected to a source electrode of a driving transistor DT and the cathode connected to a second power line VSL to which a low potential voltage that is lower than a high potential voltage is supplied.

The driving transistor DT adjusts a current flowing from a first power line VDL, to which a first power supply voltage is supplied, to the light emitting element ED according to a voltage difference between a gate electrode and a source electrode. The driving transistor DT may have the gate electrode connected to a first electrode of a first transistor ST1, the source electrode connected to the anode of the light emitting element ED, and a drain electrode connected to the first power line VDL to which a high potential voltage is applied.

The first transistor ST1 is turned on by a first scan signal of a first scan line SCL1 to connect a data line DL to the gate electrode of the driving transistor DT. The first transistor ST1 may have a gate electrode connected to the first scan line SCL1, the first electrode connected to the gate electrode of the driving transistor DT, and a second electrode connected to the data line DL.

A second transistor ST2 is turned on by a second scan signal of a second scan line SCL2 to connect an initialization voltage line VIL to the source electrode of the driving transistor DT. The second transistor ST2 may have a gate electrode connected to the second scan line SCL2, a first electrode connected to the initialization voltage line VIL, and a second electrode connected to the source electrode of the driving transistor DT.

The first electrode of each of the first and second transistors ST1 and ST2 may be a source electrode, and the second electrode thereof may be a drain electrode. However, the present disclosure is not limited thereto. That is, in some embodiments, the first electrode of each of the first and second transistors ST1 and ST2 may be a drain electrode, and the second electrode thereof may also be a source electrode.

A capacitor Cst is formed between the gate electrode and the source electrode of the driving transistor DT. The capacitor Cst stores a difference voltage between a gate voltage and a source voltage.

Although each of the driving transistor DT and the first and second transistors ST1 and ST2 is mainly described as an N-type metal oxide semiconductor field effect transistor (MOSFET) in FIG. 7, it should be noted that the present disclosure is not limited thereto. In some embodiments, each of the driving transistor DT and the first and second transistors ST1 and ST2 may be formed as a P-type MOSFET.

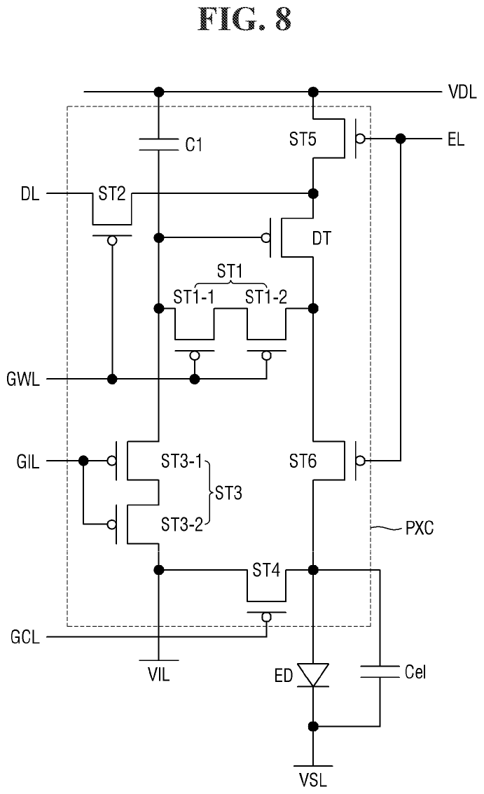

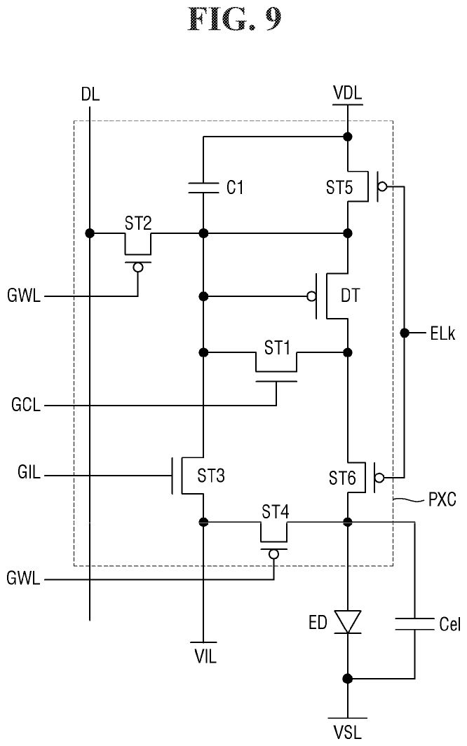

FIGS. 8 and 9 are circuit diagrams of pixels of display devices according to embodiments. FIGS. 8 and 9 illustrate other examples of the pixel circuit diagram of one pixel PX of FIG. 2. The embodiments corresponding to FIG. 9 is different from the embodiments corresponding to FIG. 8 in that a driving transistor DT, a second transistor ST2, a fourth transistor ST4, a fifth transistor STS, and a sixth transistor ST6 are formed as P-type MOSFETs, and a first transistor ST1 and a third transistor ST3 are formed as N-type MOSFETs.

Referring to FIG. 8, an anode of a light emitting element ED may be connected to a first electrode of a fourth transistor ST4 and a second electrode of a sixth transistor ST6, and a cathode may be connected to a second power line VSL. A parasitic capacitance Cel may be formed between the anode and the cathode of the light emitting element ED.

A pixel PX includes a driving transistor DT, switch elements, and a capacitor C1. The switch elements include first through sixth transistors ST1 through ST6.

The driving transistor DT includes a gate electrode, a first electrode, and a second electrode. The driving transistor DT controls a driving current, which is a drain-source current flowing between the first electrode and the second electrode of the driving transistor DT, according to a data voltage applied to the gate electrode.

The capacitor C1 is formed between the gate electrode of the driving transistor DT and a first power line VDL. One electrode of the capacitor C1 may be connected to the gate electrode of the driving transistor DT, and the other electrode may be connected to the first power line VDL.

When a first electrode of each of the first through sixth transistors ST1 through ST6 and the driving transistor DT is a source electrode, a second electrode may be a drain electrode. Alternatively, when the first electrode of each of the first through sixth transistors ST1 through ST6 and the driving transistor DT is a drain electrode, the second electrode may be a source electrode.

An active layer of each of the first through sixth transistors ST1 through ST6 and the driving transistor DT may be formed of any one of polysilicon, amorphous silicon, and an oxide semiconductor. When a semiconductor layer of each of the first through sixth transistors ST1 through ST6 and the driving transistor DT is formed of polysilicon, a process for forming the semiconductor layer may be a low-temperature polysilicon (LTPS) process.

In addition, although the first through sixth transistors ST1 through ST6 and the driving transistor DT are mainly described as P-type MOSFETs in FIG. 8, the present disclosure is not limited thereto, and they may also be formed as N-type MOSFETs.

Further, a first power supply voltage of the first power line VDL, a second power supply voltage of the second power line VSL, and a third power supply voltage of an initialization voltage line VIL may be set in consideration of characteristics of the driving transistor DT and characteristics of the light emitting element ED.

Referring to FIG. 9, an active layer of each of the driving transistor DT, the second transistor ST2, the fourth transistor ST4, the fifth transistor ST5, and the sixth transistor ST6 formed as P-type MOSFETs may be made of polysilicon, and an active layer of each of the first transistor ST1 and the third transistor ST3 formed as N-type MOSFETs may be made of an oxide semiconductor.

The embodiments corresponding to FIG. 9 is different from the embodiments corresponding to FIG. 8 in that a gate electrode of the second transistor ST2 and a gate electrode of the fourth transistor ST4 are connected to a write scan line GWL, and a gate electrode of the first transistor ST1 is connected to a control scan line GCL. In FIG. 9, because the first transistor ST1 and the third transistor ST3 are formed as N-type MOSFETs, a scan signal of a gate-high voltage may be transmitted to the control scan line GCL and an initialization scan line GIL. In contrast, because the second transistor ST2, the fourth transistor ST4, the fifth transistor ST5, and the sixth transistor ST6 are formed as P-type MOSFETs, a scan signal of a gate-low voltage may be transmitted to the write scan line GWL and an emission line EL.

A process of fabricating the display device 10 will now be described with further reference to other drawings.

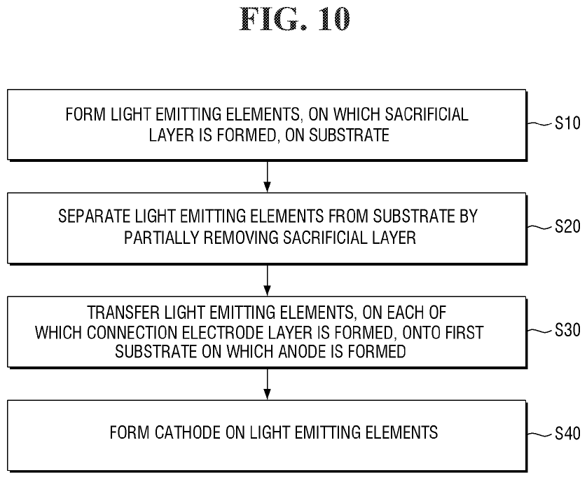

FIG. 10 is a flowchart illustrating a process of fabricating a display device according to one or more embodiments. FIGS. 11 through 16 are cross-sectional views illustrating a part of the process of fabricating the display device according to one or more embodiments.

Referring to FIGS. 10 through 16, the method of fabricating the display device 10 may include forming light emitting elements ED, on which a sacrificial layer is formed, on a substrate (operation S10), separating the light emitting elements ED from the substrate by partially removing the sacrificial layer (operation S20), transferring the light emitting elements ED, on each of which a connection electrode layer is formed, by the partial removing of the sacrificial layer, onto a first substrate on which an anode is formed (operation S30), and forming a cathode CE on the light emitting elements ED (operation S40).

First, as illustrated in FIG. 11, a base substrate BSUB is prepared, and a plurality of semiconductor material layers SEML3, SEML2, SLTL, MQWL, EBLL, SEML1, and IELL and a sacrificial layer SCL are formed on the base substrate BSUB. The base substrate BSUB may be a sapphire (Al₂O₃) substrate or a silicon wafer including silicon. However, the present disclosure is not limited thereto, and a case where the base substrate BSUB is a sapphire substrate will be described below as an example.

When the base substrate BSUB is prepared, the semiconductor material layers SEML3, SEML2, SLTL, MQWL, EBLL, SEML1, and IELL are formed on the base substrate BSUB. The semiconductor material layers SEML3, SEML2, SLTL, MQWL, EBLL, SEML1, and IELL may be formed through an epitaxial growth method. The epitaxial growth process may be electron beam deposition, physical vapor deposition (PVD), chemical vapor deposition (CVD), plasma laser deposition (PLD), dual-type thermal evaporation, sputtering, or metal organic chemical vapor deposition (MOCVD). For example, the epitaxial growth process may be performed by MOCVD, but the present disclosure is not limited thereto.

A precursor material for forming the semiconductor material layers SEML3, SEML2, SLTL, MQWL, EBLL, SEML1, and IELL is not particularly limited within a range of materials that can be generally selected to form a target material. For example, the precursor material may be a metal precursor including an alkyl group such as a methyl group or an ethyl group. For example, the metal precursor may be, but is not limited to, a compound such as trimethyl gallium (Ga(CH₃)₃), trimethyl aluminum (Al(CH₃)₃), or triethyl phosphate (C₂H₅)₃PO₄.

Although a single third semiconductor material layer SEML3 is stacked in the drawing, the present disclosure is not limited thereto, and a plurality of layers may also be formed. The third semiconductor material layer SEML3 may be located to reduce a difference in lattice constant between a second semiconductor material layer SEML2 and the base substrate BSUB. For example, the third semiconductor material layer SEML3 may include an undoped semiconductor and may be a material not doped with an n type or a p type. In one or more embodiments, the third semiconductor material layer SEML3 may be, but is not limited to, at least any one of undoped InAlGaN, GaN, AlGaN, InGaN, AlN, and InN.

The second semiconductor material layer SEML2, a superlattice material layer SLTL, an active material layer MQWL, an electron blocking material layer EBLL, a first semiconductor material layer SEML1, and an electrode material layer IELL are sequentially formed on the third semiconductor material layer SEML3 using the above-described method, and the sacrificial layer SCL is formed on the electrode material layer IELL. The sacrificial layer SCL may be formed through deposition, sputtering, or atomic layer deposition other than the epitaxial growth method.

The sacrificial layer SCL may include a material that can be chemically removed by an etching solution in a subsequent process. The sacrificial layer SCL may be partially removed by the etching solution and may be remain as a connection electrode layer SEL on each light emitting element ED. For example, the sacrificial layer SCL may include a material that can be easily chemically separated, has conductivity, and has high reflectivity. For example, the sacrificial layer SCL may include a metal material such as gold (Au), copper (Cu), tin (Sn), titanium (Ti), aluminum (Al), or silver (Ag).

Next, as illustrated in FIG. 12, the semiconductor material layers SEML3, SEML2, SLTL, MQWL, EBLL, SEML1, and IELL and the sacrificial layer SCL on the base substrate BSUB are transferred onto a temporary substrate TSUB, and the base substrate BSUB is removed. The temporary substrate TSUB may be on the sacrificial layer SCL. When the temporary substrate TSUB is located at the bottom, the electrode material layer IELL may be located at the bottom of the semiconductor material layers SEML3, SEML2, SLTL, MQWL, EBLL, SEML1, and IELL, and the base substrate BSUB may be removed to expose the third semiconductor material layer SEML3.

An etching process may be performed on the semiconductor material layers SEML3, SEML2, SLTL, MQWL, EBLL, SEML1, and IELL and the sacrificial layer SCL on the temporary substrate TSUB. The temporary substrate TSUB may include a sapphire substrate or a transparent substrate such as glass. However, the present disclosure is not limited thereto, and the temporary substrate TSUB may also be made of a conductive substrate such as GaN, SiC, ZnO, Si, GaP, or GaAs.

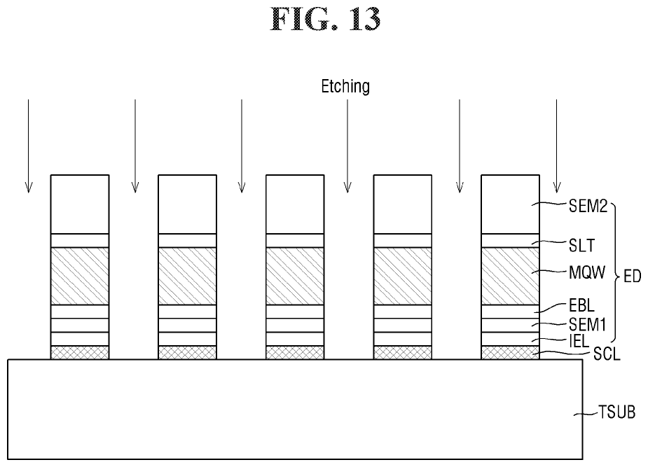

Next, referring to FIG. 13, the third semiconductor material layer SEML3 among the semiconductor material layers SEML3, SEML2, SLTL, MQWL, EBLL, SEML1, and IELL is removed, and the semiconductor material layers SEML2, SLTL, MQWL, EBLL, SEML1, and IELL and the sacrificial layer SCL are etched to form a plurality of light emitting elements ED on which the sacrificial layer SCL is formed (operation S10).

In some embodiments, the light emitting elements ED may be formed by forming a mask pattern on the semiconductor material layers SEML2, SLTL, MQWL, EBLL, SEML1, and IELL, and by etching parts where the mask pattern is not formed. The semiconductor material layers SEML2, SLTL, MQWL, EBLL, SEML1, and IELL may be etched by a conventional method. For example, the process of etching the semiconductor material layers SEML2, SLTL, MQWL, EBLL, SEML1, and IELL may be dry etching, wet etching, reactive ion etching (RIE), deep reactive ion etching (DRIE), inductively coupled plasma reactive ion etching (ICP-RIE), or the like. Dry etching may be suitable for vertical etching because anisotropic etching is possible. When the above etching methods are used, an etchant may be, but is not limited to, Cl₂ or O₂.

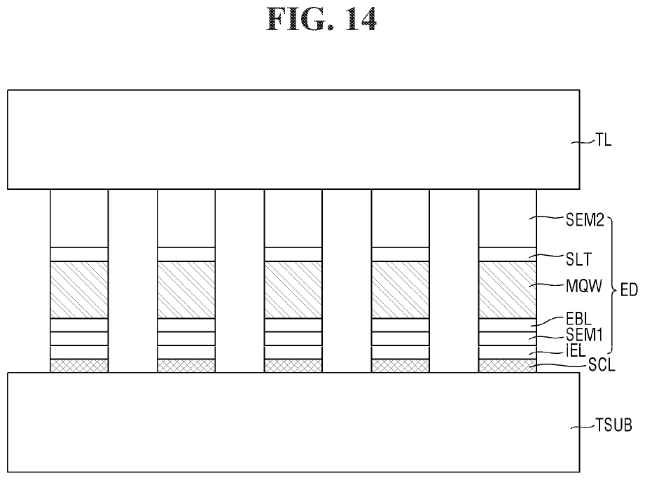

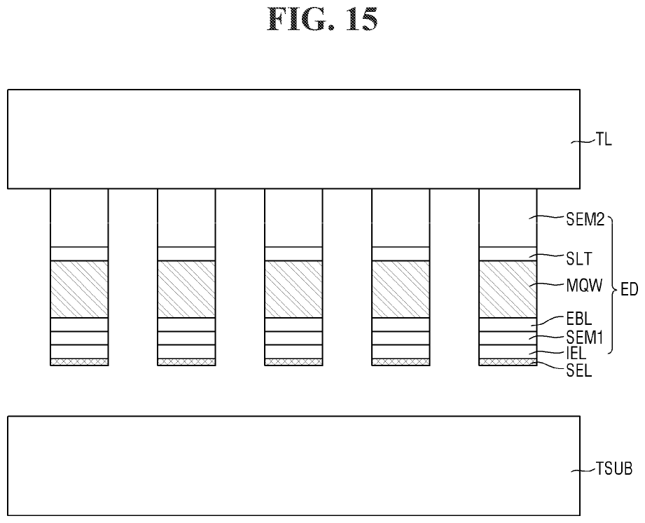

Referring to FIGS. 14 and 15, the light emitting elements ED on which the sacrificial layer SCL is formed are transferred onto a transfer film TL, and a part of the sacrificial layer SCL is removed to separate the light emitting elements ED from the temporary substrate TSUB (operation S20).

The transfer film TL may be on second semiconductor layers SEM2 of the light emitting elements ED. For example, the transfer film TL may include a stretchable material. Examples of the stretchable material may include polyolefine, polyvinyl chloride (PVC), elastomeric silicone, elastomeric polyurethane, and elastomeric polyisoprene. The transfer film TL may include a support layer and an adhesive layer to adhere to and support the light emitting elements ED on which the sacrificial layer SCL is formed.

When the transfer film TL is located, a part of the sacrificial layer SCL is removed to remove the temporary substrate TSUB thereunder. In one or more embodiments, the process of removing a part of the sacrificial layer SCL may be performed as a chemical lift-off process for removing the sacrificial layer SCL using an etching solution. A part of the sacrificial layer SCL that contacts the temporary substrate TSUB may be partially chemically removed to form the connection electrode layer SEL on an electrode layer IEL of each light emitting element ED. The connection electrode layer SEL may be a layer formed by removing a part of the sacrificial layer SCL, and a thickness of the connection electrode layer SEL may be smaller than that of the sacrificial layer SCL. An upper surface of the connection electrode layer SEL formed of the remaining sacrificial layer SCL may have a smooth shape. When the light emitting elements ED are transferred to a first substrate 110, the smooth surfaces of the connection electrode layers SEL may face anodes AE1 through AE3. The smooth surfaces of the connection electrode layers SEL may smoothly contact the anodes AE1 through AE3.

According to one or more embodiments, because the light emitting elements ED are chemically separated from the temporary substrate TSUB through the sacrificial layer SCL, their separation surfaces may be smooth. In addition, the connection electrode layers SEL formed of the remaining sacrificial layer SCL on the electrode layers IEL of the light emitting elements ED may have smooth separation surfaces from the temporary substrate TSUB, and may smoothly contact the anodes AE1 through AE3. In the display device 10, when the light emitting elements ED are electrically connected to the anodes AE1 through AE3 through the connection electrode layers SEL, the likelihood of a contact failure between the connection electrode layers SEL and the anodes AE1 through AE3 can be reduced or prevented.

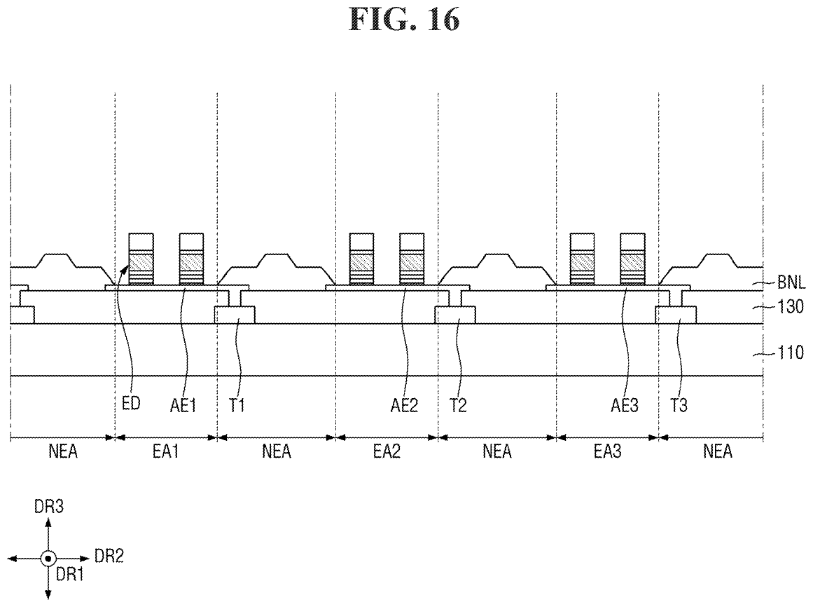

Next, as illustrated in FIG. 16, the light emitting elements ED on which the connection electrode layers SEL are formed by the removal of the sacrificial layer SCL are transferred onto the first substrate 110 on which the anodes AE1 through AE3 are located in emission areas EA1 through EA3, respectively (operation S30). The light emitting elements ED may be transferred such that the connection electrode layers SEL on first semiconductor layers SEM1 and the electrode layers IEL directly contact the anodes AE1 through AE3. When the light emitting elements ED are on the anodes AE1 through AE3, the transfer film TL is removed.

Next, in some embodiments, a second insulating layer 150 and a cathode CE are formed on the light emitting elements ED (operation S40), and a partition wall PW, light conversion layers WCL, a light blocking member BK, and color filters CF1 through CF3 are formed to fabricate the display device 10.

Various embodiments of the display device 10 will now be described with further reference to other drawings.

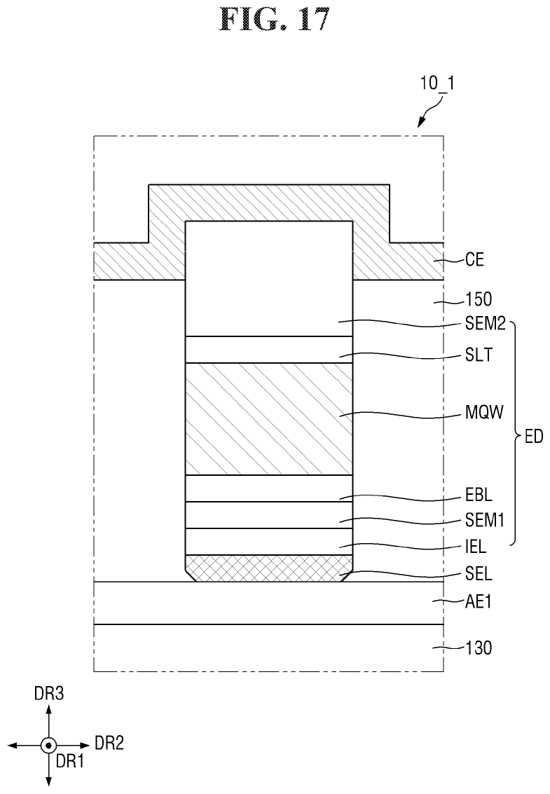

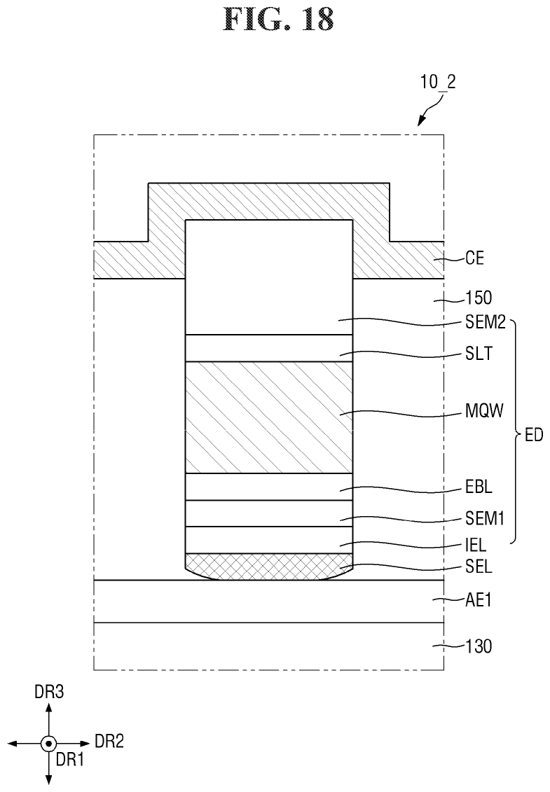

FIG. 17 is a cross-sectional view of a light emitting element ED included in a display device 10_1 according to one or more embodiments. FIG. 18 is a cross-sectional view of a light emitting element ED included in a display device 10_2 according to one or more embodiments.

Referring to FIGS. 17 and 18, the display devices 10_1 and 10_2 according to the embodiments may be different from that of the embodiments corresponding to FIGS. 5 and 6 in the shape of a connection electrode layer SEL. The connection electrode layer SEL is formed by chemically removing a sacrificial layer SCL in a process of separating the light emitting element ED from a temporary substrate TSUB. In this process, the shape of the connection electrode layer SEL may be controlled by adjusting the type of an etching solution for removing the sacrificial layer SCL, processing conditions, etc.

In the embodiments corresponding to FIGS. 5 and 6, a surface of the connection electrode layer SEL, that is, a first surface in contact with an electrode layer IEL may be parallel to a second surface in contact with an anode AE1, AE2, or AE3, and the first surface and the second surface may have the same width. On the other hand, in the embodiments corresponding to FIG. 17, the first surface of the connection electrode layer SEL may be partially parallel to the second surface, but an outer part of the second surface may be inclined. Alternatively, as in the embodiments corresponding to FIG. 18, the second surface of the connection electrode layer SEL may be partially curved.

In each of the display device 10_1 of FIG. 17 and the display device 10_2 of FIG. 18, in the process of removing the sacrificial layer SCL, the second surface which is a separation surface of the connection electrode layer SEL may be formed not to be completely parallel to the first surface. In each of the display devices 10_1 and 10_2 of FIGS. 17 and 18, the first surface of the connection electrode layer SEL may have a greater width than a part of the second surface that contacts the anode AE1, AE2, or AE3, and a part of the second surface of the connection electrode layer SEL that is not parallel to the first surface may be inclined or curved. A part of the second surface of the connection electrode layer SEL that is parallel to the first surface may contact the anode AE1, AE2, or AE3, and a part of the second surface that is not parallel to the first surface may be spaced apart from the anode AE1, AE2, or AE3.

Although the second surface of the connection electrode layer SEL is not completely parallel to the first surface, and thus does not completely contact the anode AE1, AE2, or AE3, most of the second surface may be formed to be parallel to the first surface. Accordingly, the light emitting element ED may form a smooth electrical connection with the anode AE1, AE2, or AE3 through the connection electrode layer SEL.

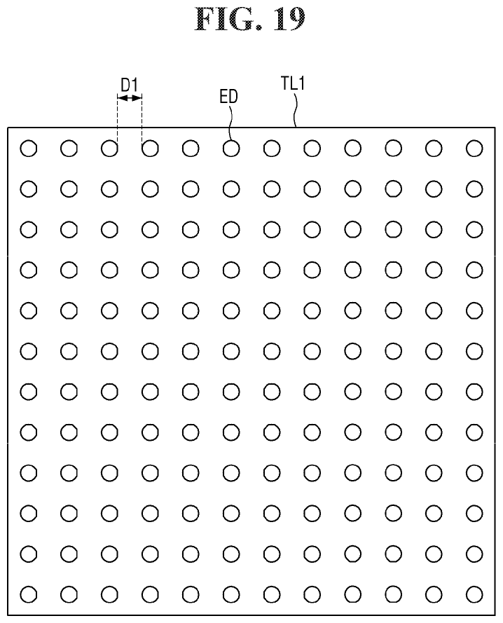

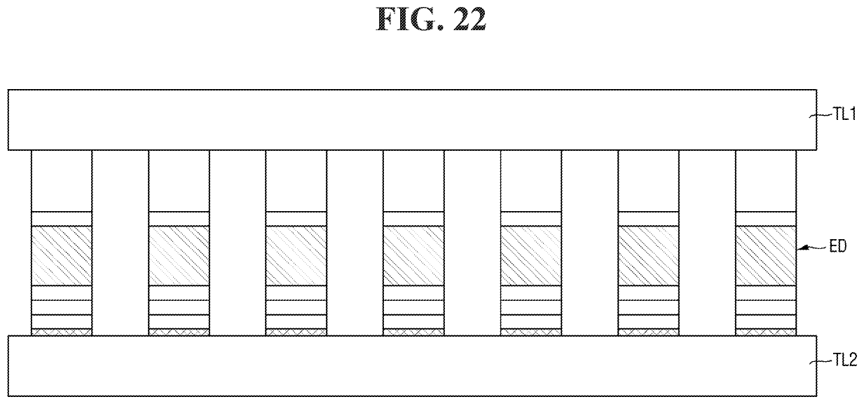

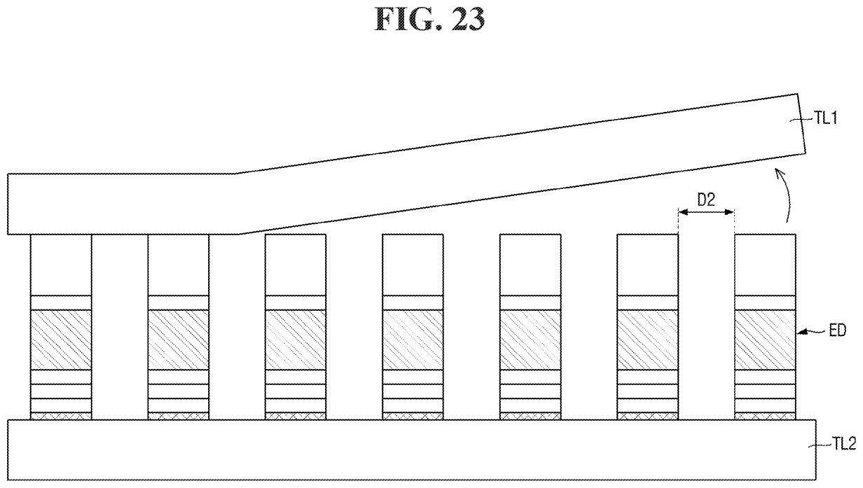

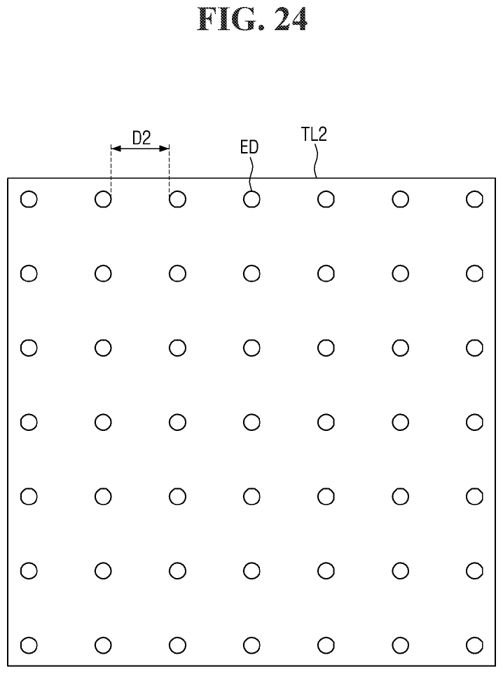

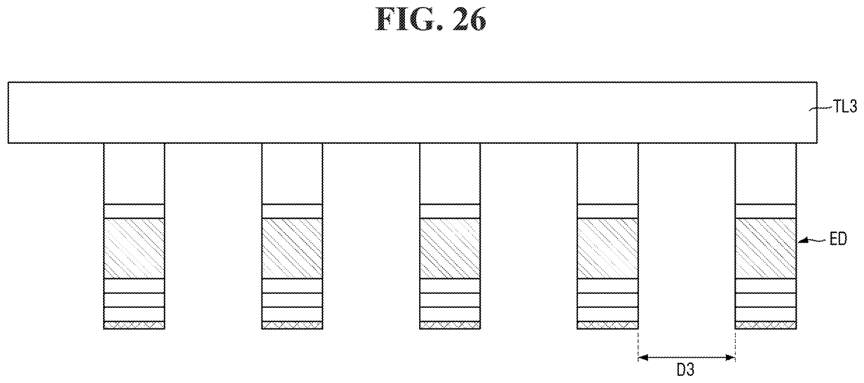

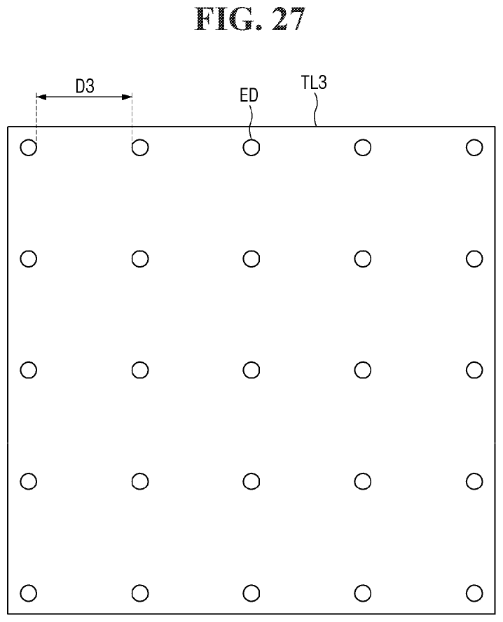

FIGS. 19 through 27 are views illustrating some operations of a transfer process of light emitting elements ED during a process of fabricating a display device 10 according to one or more embodiments.

Referring to FIGS. 19 through 27, in the transfer process of the light emitting elements ED using a transfer film TL during the process of fabricating the display device 10, a process of adjusting a distance between the light emitting elements ED using a plurality of transfer films TL1 through TL3 may be further performed.

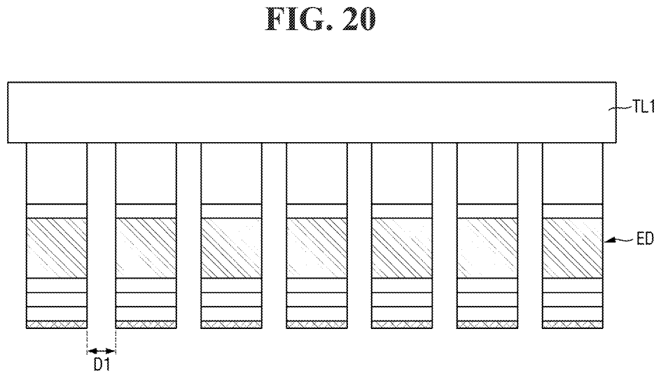

First, as illustrated in FIGS. 19 and 20, the light emitting elements ED transferred onto a first transfer film TL1 may be spaced apart from each other by a first distance D1. When the light emitting elements ED spaced apart by the first distance D1 are transferred onto a first substrate 110 as they are, too many light emitting elements ED may be located per area of emission areas EA1 through EA3. Because the light emitting elements ED are spaced apart by the relatively small first distance D1, the number of the light emitting elements ED per unit area of the first transfer film TL1 may be greater than the number of the light emitting elements ED per unit area of each of the emission areas EA1 through EA3. As described above, because the transfer film TL may be made of a stretchable material, the distance between the light emitting elements ED may be increased by stretching the first transfer film TL1.

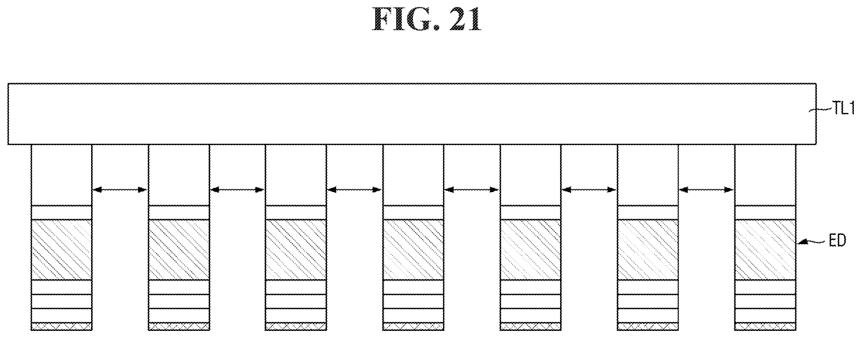

As illustrated in FIGS. 21 through 24, the distance between the light emitting elements ED is increased by stretching the first transfer film TL1 in one direction and the other direction. In this state, the light emitting elements ED on the first transfer film TL1 are transferred to a second transfer film TL2. The light emitting elements ED transferred onto the second transfer film TL2 may be spaced apart from each other by a distance that is greater than the first distance D1 in a state where the second transfer film TL2 is not stretched.

The light emitting elements ED on the second transfer film TL2 may be spaced apart from each other by a second distance D2 that is greater than the first distance D1. Because the light emitting elements ED are transferred such that connection electrode layers SEL are directly on the second transfer film TL2, they may need to be retransferred so that opposite ends of the light emitting elements ED are directly on another transfer film.

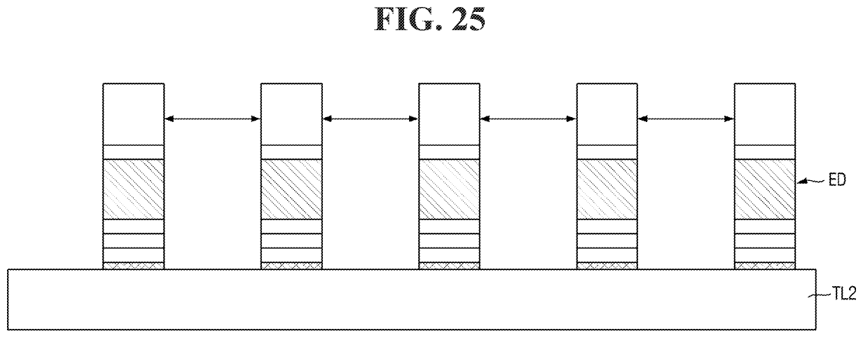

Referring to FIGS. 25 through 27, the distance between the light emitting elements ED may be increased by repeating the above-described process. The light emitting elements ED on a third transfer film TL3 may be spaced apart from each other by a third distance D3 greater than the second distance D2. Through the above-described process, the light emitting elements ED formed on a temporary substrate TSUB may be spaced apart from each other by an appropriate distance to correspond to the areas of the emission areas EA1 through EA3 of the first substrate 110.

Meanwhile, a display device for displaying an image according to one or more embodiments may be applied to various devices and apparatuses.

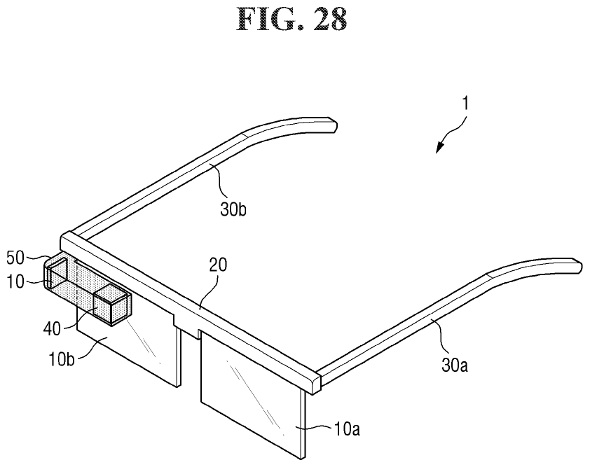

FIGS. 28 through 30 are schematic views of devices including a display device according to one or more embodiments.

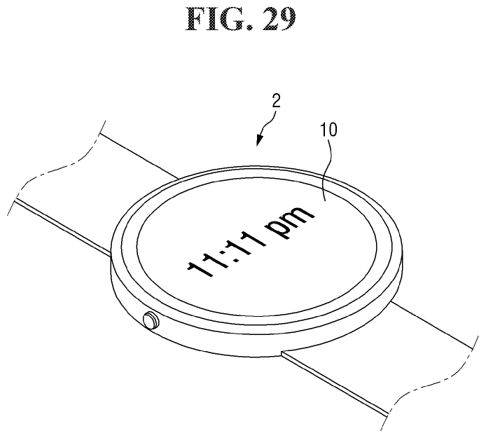

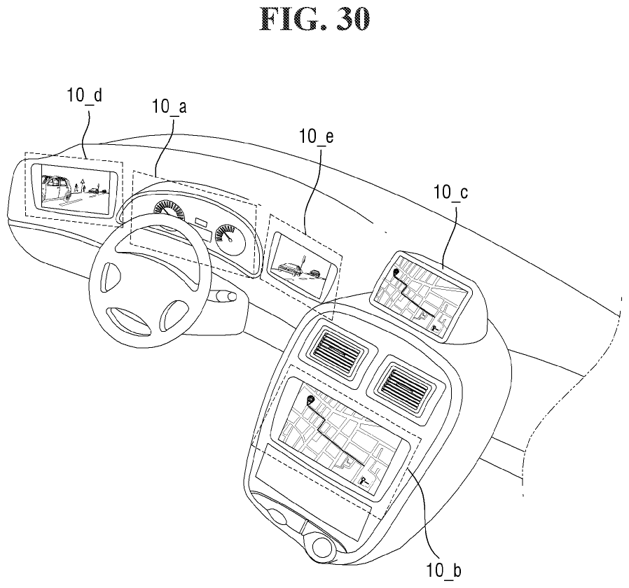

FIG. 28 illustrates a virtual reality (VR) device 1 to which a display device 10 according to one or more embodiments is applied, and FIG. 29 illustrates a smart watch 2 to which a display device 10 according to one or more embodiments is applied. FIG. 30 illustrates display units of a vehicle to which display devices 10_a through 10_e according to one or more embodiments are applied.

Referring to FIG. 28, a VR device 1 according to one or more embodiments may be a device in the form of glasses. The VR device 1 may include a display device 10, a left lens 10a, a right lens 10b, a support frame 20, eyeglass frame legs 30a and 30b, a reflective member 40, and a display device accommodating unit 50.

In the drawing, the VR device 1 including the eyeglass frame legs 30a and 30b is illustrated as an example. However, the VR device 1 may also be applied to a head-mounted display including a head-mounted band, which can be mounted on the head, instead of the eyeglass frame legs 30a and 30b. The VR device 1 is not limited to the structure illustrated in the drawing and can be applied in various forms in various other electronic devices.

The display device accommodating unit 50 may include the display device 10 and the reflective member 40. An image displayed on the display device 10 may be reflected by the reflective member 40 and provided to a user's right eye through the right lens 10b. Accordingly, the user may view a VR image displayed on the display device 10 through the right eye.

The display device accommodating unit 50 may be located at a right end of the support frame 20, but the present disclosure is not limited thereto. For example, the display device accommodating unit 50 may also be located at a left end of the support frame 20, and an image displayed on the display device 10 may be reflected by the reflective member 40 and provided to the user's left eye through the left lens 10a. Accordingly, the user may view a VR image displayed on the display device 10 through the left eye. Alternatively, the display device accommodating unit 50 may be located at both the right end and the left end of the support frame 20. In this case, the user may view a VR image displayed on the display device 10 through both the left eye and the right eye.

Referring to FIG. 29, a display device 10 according to one or more embodiments may be applied to a smart watch 2 which is one of smart devices.

Referring to FIG. 30, display devices 10_a through 10_c according to one or more embodiments may be applied to a dashboard of a vehicle, a center fascia of the vehicle, or a center information display (CID) on the dashboard of the vehicle. In addition, display devices 10_d and 10_e according to one or more embodiments may be applied to room mirror displays that replace side mirrors of the vehicle.

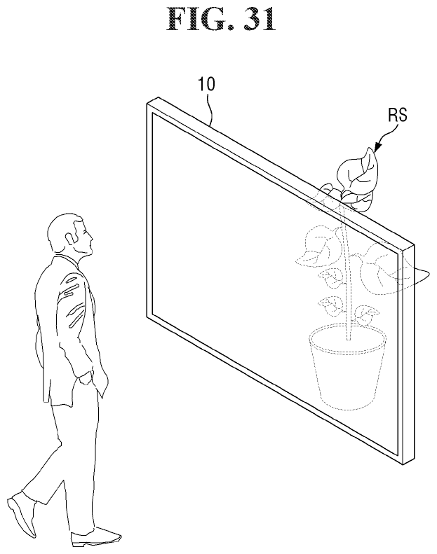

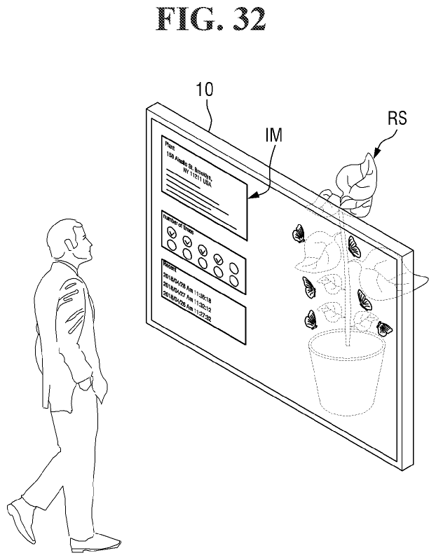

FIGS. 31 and 32 illustrate a transparent display device including a display device 10 according to one or more embodiments.

Referring to FIGS. 31 and 32, the display device 10 may be applied to the transparent display device. The transparent display device may transmit light while displaying an image IM. A user in front of the transparent display device may not only view the image IM displayed on the display device 10 but also view an object RS or the background located behind the transparent display device.

A light emitting element according to one or more embodiments may go through a separation process performed using a sacrificial layer during a fabrication process, and a connection electrode layer having a smooth separation surface may be formed.

A display device according to one or more embodiments may include a light emitting element on which a connection electrode layer is formed. Therefore, the likelihood of an electrical connection failure between the light emitting element and an anode can be reduced or prevented, and upward light emission efficiency can be improved.

In concluding the detailed description, those skilled in the art will appreciate that many variations and modifications can be made to the embodiments without substantially departing from the present disclosure. Therefore, the disclosed embodiments are used in a generic and descriptive sense only and not for purposes of limitation.

What is claimed is:

1. A display device comprising:
a pixel electrode on a substrate;
a light emitting element on the pixel electrode, and comprising a first semiconductor layer, an active layer on the first semiconductor layer, and a second semiconductor layer on the active layer;
a connection electrode layer between the light emitting element and the pixel electrode, and directly contacting the pixel electrode;
an insulating layer on the substrate and the pixel electrode, and surrounding the light emitting element; and
a common electrode on the insulating layer directly contacting the second semiconductor layer of the light emitting element.

2. The display device of claim 1, wherein the light emitting element further comprises an electrode layer between the connection electrode layer and the first semiconductor layer, and
wherein the connection electrode layer comprises a first surface in contact with the electrode layer, and a second surface in contact with the pixel electrode,
wherein the first surface is parallel to at least a part of the second surface.

3. The display device of claim 2, wherein a width of the first surface of the connection electrode layer is the same as a width of the light emitting element.

4. The display device of claim 2, wherein the first surface has a same width as the second surface.

5. The display device of claim 2, wherein a part of the second surface is parallel to the first surface, and another part of the second surface is not parallel to the first surface.

6. The display device of claim 5, wherein the part of the second surface that is parallel to the first surface directly contacts the pixel electrode, and
wherein the part of the second surface that is not parallel to the first surface is spaced apart from the pixel electrode.

7. The display device of claim 5, wherein the part of the second surface that is not parallel to the first surface is inclined.

8. The display device of claim 5, wherein the part of the second surface that is not parallel to the first surface is curved.

9. The display device of claim 2, wherein the connection electrode layer comprises at least any one of aluminum (Al), copper (Cu), silver (Ag), gold (Au), tin (Sn), and titanium (Ti), and
wherein the electrode layer of the light emitting element comprises at least any one of aluminum (Al), titanium (Ti), indium (In), gold (Au), silver (Ag), indium tin oxide (ITO), indium zinc oxide (IZO), and indium tin zinc oxide (ITZO).

10. The display device of claim 1, wherein at least a part of the light emitting element protrudes above the insulating layer.

11. The display device of claim 1, wherein the light emitting element further comprises:
an electron blocking layer between the first semiconductor layer and the active layer; and
a superlattice layer between the second semiconductor layer and the active layer.

12. The display device of claim 1, further comprising a bank layer on the substrate, overlapping a part of the pixel electrode, and not overlapping the light emitting element.

13. The display device of claim 12, further comprising:
a partition wall on the common electrode and defining an opening;
a light conversion layer in the opening; and
a color filter on the light conversion layer and the partition wall.

14. The display device of claim 13, wherein the partition wall overlaps the bank layer, and
wherein the opening overlaps the light emitting element.

15. A method of fabricating a display device, the method comprising:
forming a light emitting element by forming a sacrificial layer on a temporary substrate, forming a semiconductor material layer on the sacrificial layer, and etching the sacrificial layer and the semiconductor material layer;
separating the light emitting element from the temporary substrate by removing a part of the sacrificial layer and forming a connection electrode layer on a surface of the light emitting element; and
transferring the light emitting element, on which the connection electrode layer is formed, onto a first substrate on which pixel electrode is located.

16. The method of claim 15, wherein the light emitting element comprises an electrode layer on the connection electrode layer, a first semiconductor layer on the electrode layer, an active layer on the first semiconductor layer, and a second semiconductor layer on the active layer, and
wherein the connection electrode layer directly contacts the pixel electrode in the transferring of the light emitting element onto the first substrate.

17. The method of claim 16, wherein the connection electrode layer comprises a first surface in contact with the electrode layer, and a second surface in contact with the pixel electrode,
wherein the first surface is parallel to at least a part of the second surface.

18. The method of claim 15, wherein a thickness of the sacrificial layer is greater than a thickness of the connection electrode layer.

19. A light emitting element comprising:
a first semiconductor layer doped with a p-type dopant;
a second semiconductor layer doped with an n-type dopant;
an active layer between the first semiconductor layer and the second semiconductor layer; and
an electrode layer on a surface of the first semiconductor layer,
wherein a connection electrode layer is on a surface of the electrode layer, and comprises a first surface in contact with the electrode layer, and a second surface opposite the first surface, and
wherein the first surface is parallel to at least a part of the second surface.

20. The light emitting element of claim 19, wherein the connection electrode layer comprises at least any one of aluminum (Al), copper (Cu), silver (Ag), gold (Au), tin (Sn), and titanium (Ti), and
wherein the electrode layer of the light emitting element comprises at least any one of aluminum (Al), titanium (Ti), indium (In), gold (Au), silver (Ag), indium tin oxide (ITO), indium zinc oxide (IZO), and indium tin zinc oxide (ITZO).
